(19) United States
(12) Patent Application Publication
(10) Pub. No.: US 2011/0026571 A1
(43) Pub. Date: Feb. 3, 2011

(54) AUTOMATIC GAIN CONTROLLER, TRANSCEIVER AND AUTOMATIC GAIN-CONTROL METHOD THEREOF

(75) Inventors: Seon-Ho Han, Daejeon (KR); Mun-Yang Park, Daejeon (KR); Cheon-Soo Kim, Daejeon (KR); Jae-Young Kim, Daejeon (KR)

Correspondence Address: AMPACC Law Group, PLLC, 6100 219th Street SW, Suite 580, Mountlake Terrace, WA, 98043, US

(73) Assignee: Electronics and Telecommunications Research Institute, Daejeon (KR)

(21) Appl. No.: 12/935,569

(22) PCT Filed: Aug. 8, 2008
(86) PCT No.: PCT/KR08/04628

§ 371 Date: Sep. 29, 2010

(30) Foreign Application Priority Data
Apr. 14, 2008 (KR) 10-2008-0034310

(51) Int. Cl. H04B 3/46; H03G 3/20

(52) U.S. Cl. 375/224; 330/207 R

(57) ABSTRACT

An automatic gain-control method for a communication system is comprised of determining a communication distance between the first and second transceivers and controlling gain values of transception stages of the first and second transceivers in correspondence with the communication distance.

### TECHNICAL FIELD

The present invention provided herein relates to communication systems. In particular, the present invention is concerned with an automatic gain controller, a transceiver, and an automatic gain-control method thereof.

This invention is derived from the study for IT Development Project for Newly Promotive Source Technology by Ministry of Information and Communication of Korea (Project No. 2006-S-070-02 entitled “Cognitive wireless system development for home networks”).

### BACKGROUND ART

A communication system generally operates by accompanying with a function of automatic gain control (AGC) for automatically controlling gains of transceiving stages by means of reception signal intensity. In such a communication system, it usually adjusts an amplification gain in order to compensate distortion by fading effects that are time variation of power due to distance changes and migrations in the time of receiving signals.

FIGS. 1, 2, and 3 illustrate general configurations of automatic gain controllers (AGCs) that operate by detecting signal power levels. FIG. 1 shows an analog type of the automatic gain controllers. Referring to FIG. 1, the analog automatic gain controller 10 detects an output of an amplified analog output signal SO and maintains the output signal SO on a constant level under control by a variable gain amplifier 11 through a feedback loop. During this, a reference output signal is provided to the feedback loop in order to obtain a desired level of the output signal SO. FIG. 2 shows a feedbacked and mixed automatic gain controller 20. Referring to FIG. 2, the feedbacked and mixed automatic gain controller 20 detects a signal power level from a digitized output signal DSO and controls a variable gain controller 21 analoguely or digitally in accordance with a result of the detection. Such an automatic gain control mode is called ‘mixed mode’ because it is conducted in a mixed structure mixedly with analog and digital blocks. FIG. 3 shows a feedforwarded and mixed automatic gain controller 30. Referring to FIG. 3, the feedforwarded and mixed automatic gain controller 30 controls a variable gain controller 31 by generating a control signal directly to an input signal SI that fluctuates in level.

Those automatic gain controllers (AGCs) are disclosed in IEEE Journal of Solid-State Circuits, Vol. 41, No. 10, pp. 2291˜2300, October 2006, entitled “Analog AGC Circuitry for a CMOS WLAN Receiver” (O. Jeon, et al), IEEE Transaction on Communications, Vol. 42, No. 2/3/4, pp. 680˜688, February 1994, entitled “On Optimal AGC structure for Direct Sequence Spread Spectrum PN-code Tracking” (Arnold L. Welti, et al), and U.S. Patent Publication No. 2007/0188361A1, Aug. 16, 2007, entitled “Method and system for Mixed Analog-Digital Automatic Gain Control” (Brad Delanghe, Aleckasdr Movshovish), all of which are incorporated herein by reference.

FIG. 4 illustrates an example of an automatic gain controller that automatically controls an amplification gain by detecting a signal power level. Referring to FIG. 4, the automatic gain controller 40 includes a variable gain amplifier 41, an analog-digital converter (ADC) 42, and a digital signal processor 43. The digital signal processor 43 includes a power detector 44 and a gain controller 45. The variable gain amplifier 41 operates to adjust a gain in accordance with a level of a radio input signal SI. The input signal SI is usually converted into a digital signal DSO through the ADC 42. The power detector 44 detects a signal power level from the digital signal DSO.

From a result of the detection, the gain controller 45 decreases a gain of the variable gain amplifier 41 if it determines a signal power level is relatively small. If a signal power level is relatively large, the gain controller 45 increases a gain of the variable gain amplifier 41. An output of the gain controller 45 is able to discretely control the variable gain amplifier 41 or to analoguely control the variable gain amplifier 41 by way of a digital-analog converter (not shown). The detail about the automatic gain controller 40 shown in FIG. 4 is disclosed in U.S. Patent Publication No. 2006/0222118A1, Oct. 5, 2006, entitled “Automatic gain control for wireless receiver” (Qualcomm Incorporated), which is incorporated herein by reference.

### DISCLOSURE OF INVENTION

### Technical Problem

Accordingly, the present invention is directed to a transceiver controlling a variable gain amplifier by means of a communication distance measured when a reception signal fluctuates due to distance variation, and an automatic gain control method thereof.

The present invention is also directed to a transceiver improving a signal-to-noise ratio, and an automatic gain control method thereof.

### Technical Solution

An aspect of the present invention is an automatic gain-control method for a communication system, including: determining a communication distance between the first and second transceivers; and controlling gain values of transception stages of the first and second transceivers in correspondence with the communication distance.

In an embodiment, determining the communication distance is comprised of: generating an distance determining signal from the first transceiver; transmitting an distance determining signal from the generated second transceiver; transmitting an distance determining signal from the transmitted first transceiver; and calculating the communication distance by means of a time from the generation of the distance determining signal until the transmission of the distance determining signal.

In an embodiment, the distance determining signal is generated periodically.

In an embodiment, the gain values of the transception stages increases as long as the determined communication distance, while decreases as short as the determined communication distance.

In an embodiment, the first and second transceivers track optimal gain values in accordance with the determined communication distance at the beginning of operation in the communication system.

In an embodiment, an intermediate value among gain values in an available gain control range is selected as the gain value of the transception stage when the first or second transceiver is moving. The available gain control range is the extension traceable for migration of a target in accordance with the optimal gain value.

In an embodiment, the maximum value among gain values in an available gain control range is selected as the gain value of the transception stage when the first or second transceiver is positioned at the maximum cognition distance during migration. The maximum cognition distance corresponds to the maximum communication distance cognizable by the first and second transceivers. The available gain control range is the extension traceable for migration of a target in accordance with the optimal gain value.

Another aspect of the present invention is an automatic gain controller including: a variable-gain input amplifier amplifying a signal input from external; an analog-digital converter converting an output signal of the variable-gain input amplifier into a digital signal; a digital-analog converter converting an internal digital signal into an analog signal; a variable-gain output amplifier amplifying an output of the digital-analog converter and outputting the amplified signal to the external; and a digital signal processor processing an output of the analog-digital converter and controlling gain values of the variable-gain input and output amplifiers in correspondence with a communication distance.

In an embodiment, the digital signal processor includes: an distance determiner calibrating the communication distance; and a gain controller adjusting the gain values of the variable-gain input and output amplifiers in correspondence with the communication distance.

Still another aspect of the present invention is a transceiver including: an distance determiner calibrating a communication distance; and an automatic gain controller maintaining an output of an amplifier in accordance with the communication distance.

In an embodiment, the automatic gain controller includes: a variable-gain input amplifier amplifying a signal input from external; an analog-digital converter converting an output signal of the variable-gain input amplifier into a digital signal; a digital-analog converter converting an internal digital signal into an analog signal; a variable-gain output amplifier amplifying an output of the digital-analog converter and outputting the amplified signal to the external; and a digital signal processor processing an output of the analog-digital converter and controlling gain values of the variable-gain input and output amplifiers in correspondence with the communication distance taken by the distance determiner.

### Advantageous Effects

A communication system according to the present invention includes an automatic gain controller for controlling a gain of a transceiver in accordance with a measured value of communication distance. Thereby, it is easy to control a gain automatically even for a communication system in which it is difficult to detect a signal power level.

Additionally, the automatic gain controller is simple in architecture.

Moreover, the communication system is very effectively useful to ultra-wideband (UWB) communication networks.

### BRIEF DESCRIPTION OF THE DRAWINGS

FIGS. 1, 2, and 3 illustrate general configurations of automatic gain controllers.

FIG. 4 illustrates an example of an automatic gain controller.

FIG. 5 illustrates a communication system according to the present invention.

FIG. 6 illustrates an embodiment of an automatic gain controller according to the present invention.

FIG. 7 is a graphic view showing an operational pattern of the automatic gain controller according to the present invention to an arbitrary channel characteristic.

FIG. 8 is a flow chart showing a procedure for automatically controlling a gain by the automatic gain controller of the present invention.

FIGS. 9 and 10 are graphic diagrams showing features of tracking the optimum gain value of the communication system in accordance with the present invention.

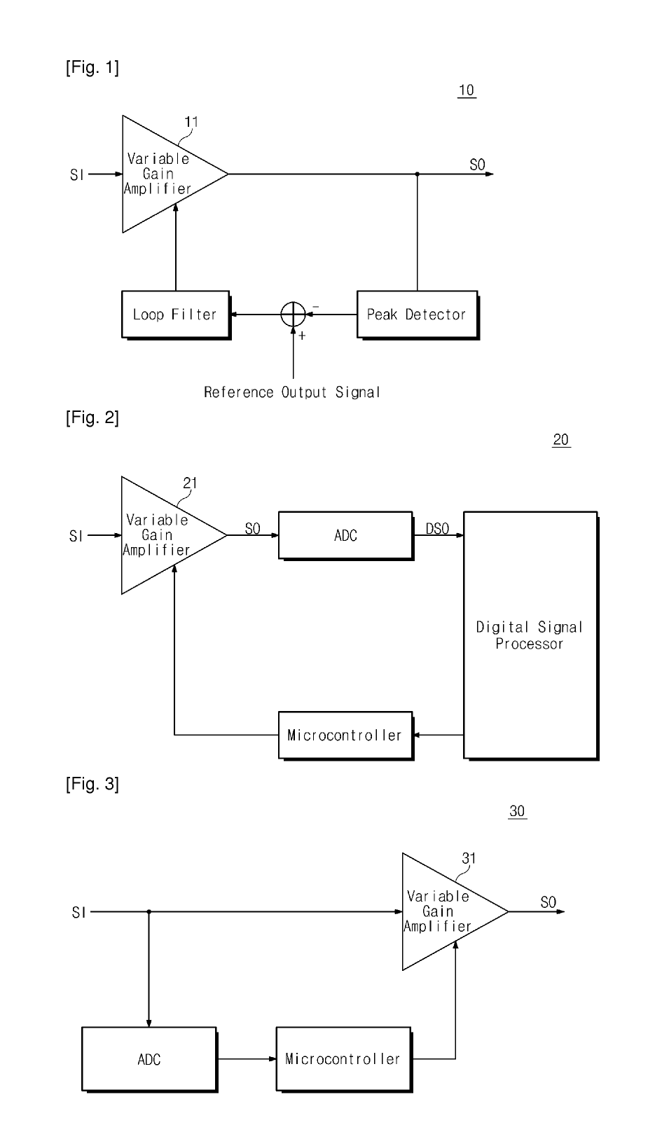

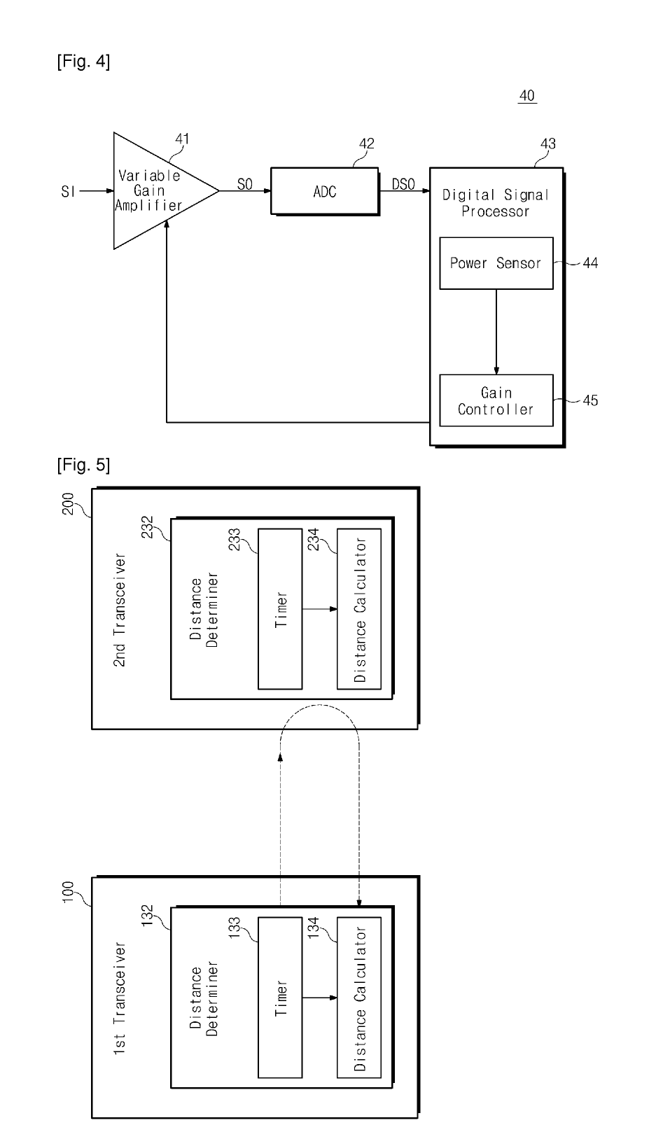

### BEST MODE FOR CARRYING OUT THE INVENTION

Hereinafter, preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

An automatic gain controller according to the present invention is designed to control a gain of a transceiver in correspondence with a measured communication distance. And, a communication system including the automatic gain controller of the present invention is able to automatically control an amplification gain even in communication environments in which it is difficult to detect a signal power level.

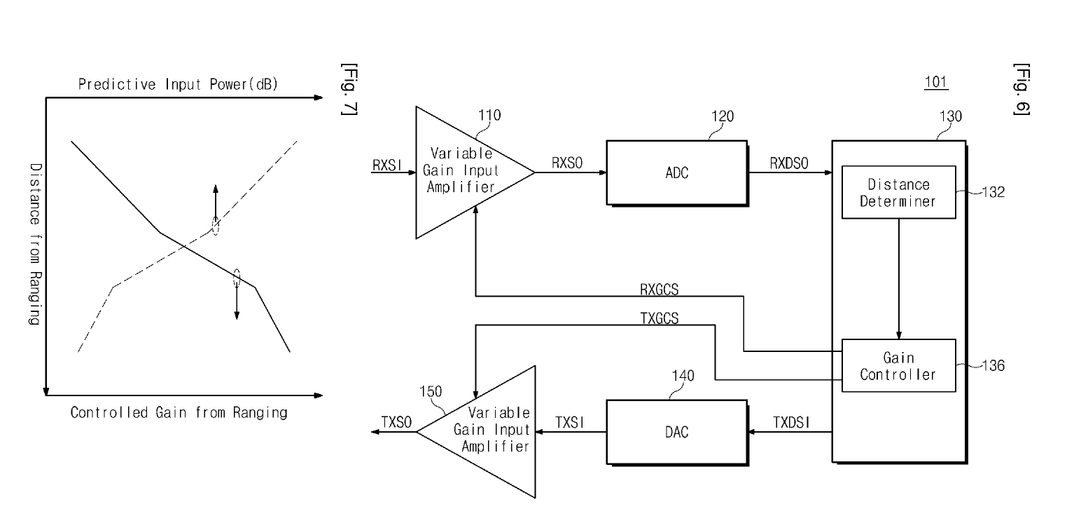

FIG. 5 illustrates the communication system according to the present invention. Referring to FIG. 5, the communication system of the present invention is comprised of first and second transceivers 100 and 200 including distance determiners 132 and 232 respectively. Hereinafter, this communication system will be referred to as ‘distance-determined communication system’. The distance determiners 132 and 232 measure a communication distance between the first and second transceivers 100 and 200. Here, the communication distance means a distance between the first and second transceivers 100 and 200. The first and second transceivers 100 and 200 control a gain at the transception stage in correspondence with a measured (or determined) communication distance.

As shown in FIG. 5, the distance determiner 132 of the first transceiver 100 is comprised of a timer 133 and an distance calculator 134. The distance determiner 132 generates an distance determining signal at the beginning of communication and transmits the distance determining signal to the second transceiver 200. Then, the second transceiver 200 receives the distance determining signal and transmits the distance determining signal to the first transceiver 100. The timer 133 of the first transceiver 100 measures a time from transmitting the distance determining signal until receiving the distance determining signal transmitted from the second transceiver 200. The distance calculator 134 operates to calculate a communication distance between the first and second transceivers 100 and 200 by means of a time measured by the timer 134. Here, the distance calculator 134 obtains a communication distance with reference to a propagation time, a propagation rate, and data processing times in the transceivers 100 and 200.

In the communication system, the distance determiners 132 and 232 are organized of the timers 133 and 233 and the distance calculators 134 and 234. But it may be understood by those skilled in the art that the communication system of the present invention is not restrictive to the structure with the timers and distance calculators. The distance determiner employed in the communication system of the present invention may be another type of distance determining means but the feature of detecting a signal power level.

The communication system according to the present invention can be also utilized for a position tracking system. The communication invention according to the present invention is applicable to an distance determination system using ultra-wideband (UWB). For instance, the communication system by the present invention can be employed in applications such as logistics, robot tracking, and human following, which are operating in tracking density under the level of tens centimeters while minimizing interference.

A conventional communication system using UWB operates with detecting a level of a UWB signal. However, since such UWB signals are conveyed so intermittently (or periodically), it is difficult to detect a signal power level. Consequently, such a conventional UWB communication system is unable to control an amplification gain in correspondence with a communication distance or distance. Namely, the conventional UWB communication system is low in the facility of signal reception and limited to cognition distance (or cognition range) for a communication target.

Differently, the communication system according to the present invention is configured to determine a communication distance without detecting a signal power level. In other words, the communication system of the present invention controls an amplification gain in correspondence (or accordance) with a communication distance determined thereby. Thus, it is able to adjust an amplification gain according to a communication distance, enhancing signal reception facility and hence extending a cognition distance for a target.

FIG. 6 illustrates an embodiment of an automatic gain controller according to the present invention, exemplarily showing the automatic gain controller 101 of the first transceiver 100 shown in FIG. 5. Referring to FIG. 6, the automatic gain controller 101 is comprised of a variable-gain input amplifier 110, an analog-digital converter (ADC) 120, a digital signal processor 130, a digital-analog converter (DAC) 140, and a variable-gain output amplifier 150. The automatic gain controller 101 according to the present invention operates to automatically control the variable-gain input and output amplifiers 110 and 150 in accordance with a determined communication distance.

In a reception mode, the variable-gain input amplifier 110 operates to amplify a reception signal RXSI. Then, the ADC 120 converts an output signal RXSO of the variable-gain input amplifier 110 into a digital signal. The DAC 130 processes an output signal RXDSO of the ADC 120. The digital signal processor 130 includes the distance determiner 132. The gain controller 136 operates to automatically adjust a gain of the variable-gain input amplifier 110 in correspondence with the determined communication distance. Owing to this automatic control scheme for amplification gain, the output signal RXSO of the variable-gain input amplifier 110 is maintained in a constant level.

In a transmission mode, the digital signal processor 130 generates a digital signal TXDSI. The DAC 140 receives the digital signal TXDSI output from the digital signal processor 130 and converts the digital signal TXDSI into an analog signal TXSI. The variable-gain output amplifier 150 operates to amplify the output signal TXSI of the DAC 140. A signal output from the variable-gain output amplifier TXSO is transmitted to the other transceiver. The gain controller 136 operates to automatically control a gain of the variable-gain output amplifier 150 in accordance with the determined communication distance. This automatic control scheme for amplification gain enables the output signal RXSO of the variable-gain input amplifier 110 to be maintained in a constant level.

The gain controller 136 according to the present invention generates gain control signals RXGCS and TXGCS for controlling the variable-gain input and output amplifiers 110 and 150. The variable-gain input and output amplifiers 110 and 150 operate in compliance with the control signals RXGCS and TXGCS, respectively. Generally, the gain controller 136 is designed to increase a gain value as long as a communication distance, while to decrease a gain value as short as a communication distance. Namely, the control signals RXGCS and TXGCS, which are generated from the gain controller 136, function to keep the output signals RXSO and TXSO of the variable-gain input and output amplifiers 110 and 150, respectively. The gain controller 136 may be configured to control a transmission stage only, a reception stage only, or both of the transmission and reception stages.

In the meantime, the scheme with the variable-gain input and output amplifiers 110 and 150 may be implemented in an analog, digital, or mixed mode. That is, the variable-gain input and output amplifiers 110 and 150 may be made up with analog or digital amplifiers. If the variable-gain amplifiers are formed to be operable in analog mode, the control signals RXGCS and TXGCS become analog signals. If the variable-gain amplifiers are formed to be operable in digital mode, the control signals RXGCS and TXGCS become digital signals.

Further, the gain controller 136 according to the present invention stores the optimal gain values according to the determined communication distance. The optimal gain values stored therein are referred in setting levels of the control signals RXGCS and TXGCS.

The transceiver according to the present invention is comprised of the automatic gain controller for adjusting amplification gains according to a determined communication distance.

In the transceiver according to the present invention, the digital signal processor includes the distance determiner for surveying a communication distance as shown in FIG. 6. Bit it may not be restrictive to the fact that the distance determiner is included in the digital signal processor. The distance determiner for calibrating a communication distance may be out of the automatic gain controller in the transceiver. As a result, is able to construct for the transceiver of the present invention to include the distance determiner for calibrating a communication distance, and the automatic gain controller for adjusting an amplification gain of the variable gain controller.

FIG. 7 is a graphic view showing an operational pattern of the automatic gain controller according to the present invention to an arbitrary channel characteristic. Referring to FIG. 7, a power level of a reception signal decreases as long as a communication distance. Thus, a gain adjusted by the variable gain controller. The automatic gain controller according to the present invention is configured to optimally adjust an amplification gain by an efficient operation therefor.

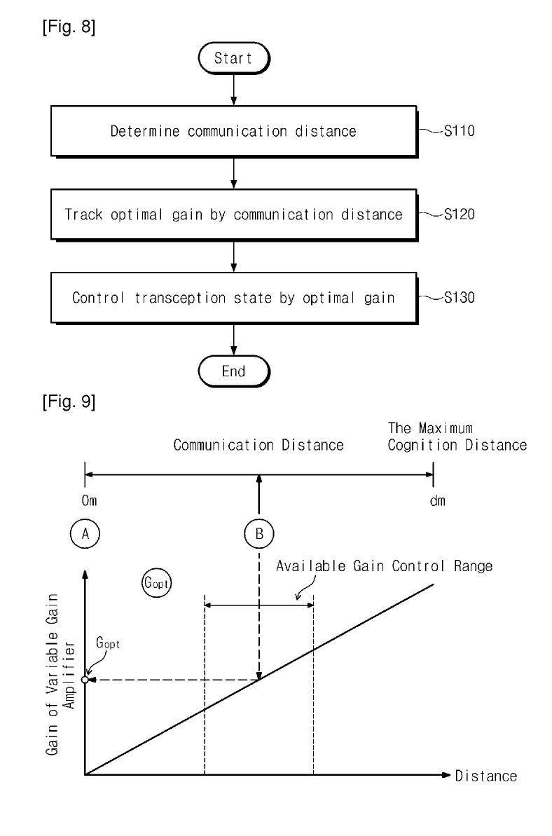

FIG. 8 is a flow chart showing a procedure for automatically controlling a gain by the automatic gain controller of the present invention. Referring to FIGS. 5 through 8, the automatic gain control method according to the present invention is as follows. For convenience of description, it is assumed that only the first transceiver 100 is able to conduct the automatic gain control operation. But it should be appreciated that the present invention does not any restriction hereto about the side of the transceivers in which the automatic gain control is conducted. The automatic gain control operation can be also carried out in both of the first and second transceivers 100 and 200 at the same time.

At the beginning of communication, the distance determiner 132 of the first transceiver 200 calibrates a communication distance between the first and second transceivers 100 and 200 (S110). The distance determiner 132 generates and transmits the distance determining signal to the second transceiver 200 for calibrating the communication distance. The second transceiver 200 transmits the received distance determining signal to the first transceiver 100. The distance determiner 132 counts a time from the generation unto the reception of the distance determining signal, and calculates the communication distance in accordance with the counted time. Here, the procedure of determining a communication distance will not be further detailed because it has been done before in conjunction with FIG. 5.

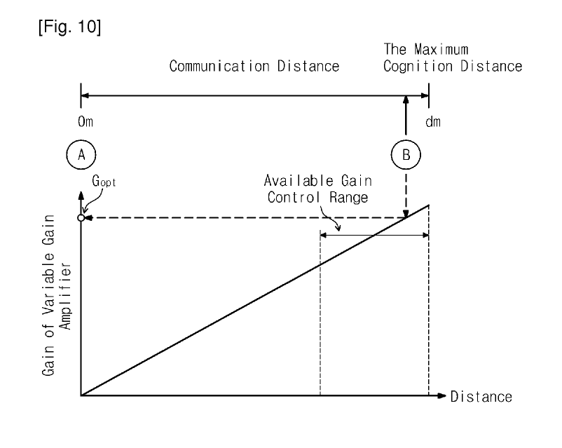

The second transceiver 200, i.e., a communication target, may be conditioned in movement. During this, in order to set the transception stages on the optimal gain value in correspondence with the determined communication distance, the first transceiver 100 is needed to track the optimal gain value. If the second transceiver 200 is moving, the first transceiver 100 follows the optimal gain value of its transception stage (S120). The details about tracking the optimal gain value will be described later with reference to FIGS. 9 and 10. The first transceiver 100 controls its transception stage to the optimal gain value that has been traced (S130). Thereafter, the first and second transceivers 100 and 200 conduct communication with each other in accordance with the optimal gain value.

The methodological feature by the automatic gain controller, shown in FIG. 8, is just an embodiment, so it may be variously modified by the present invention.

FIGS. 9 and 10 are graphic diagrams showing features of tracking the optimum gain value of the communication system in accordance with the present invention. Hereinafter, the first and second transceivers 100 and 200 will be referred to as A and B, respectively. FIG. 9 shows a pattern of tracking the optimal gain value when B is in an intermediate position of the maximum cognition distance d. Here, the maximum cognition distance d corresponds to the maximum communication distance detectable by A. Gopt denotes a gain value at an arbitrary communication distance. An available gain control range is defined as the extension of gain values with which A is able to track B in an arbitrary communication distance. If B moves out of the available gain control range, A is unable to find a location of B. In the beginning of communication between A and B, there may be initially a case incapable of identifying the target B to be traced. At this time, A has to find the target B by varying a gain value in a traceable range of communication distances. Finding the target B, A operates to control a gain value of its transception stage according to the communication distance by selecting the optimal gain value Gopt.

As seen from the graph of FIG. 9, if B is located in an intermediate position of the maximum cognition distance d, it selects an intermediate gain value as the optimal gain value Gopt in the available gain control range corresponding to the communication distance. This makes it possible to flexibly adapt to migration of the communication target B.

Meanwhile, referring to FIG. 10, the target B may be placed around the maximum cognition distance d. In this case, the optimal gain value Gopt is selected from the maximum value around the maximum cognition distance in the available gain control range.

The transceiver according to the present invention is employable in a communication system. The communication system according to the present invention includes the first and second transceivers that conduct the operation of automatic gain control in correspondence with a determined communication distance. Each of the first and second transceivers includes the distance determiner for calibrating the communication distance.

Each of the first and second transceivers also includes the automatic gain controller for conducting the automatic gain control operation in accordance with the determined communication distance. The automatic gain controller includes: the variable-gain input amplifier for amplifying an external signal input thereto; the ADC for converting an output signal of the variable-gain input amplifier into a digital signal; the DAC for converting an internal digital signal into an analog signal; the variable-gain output amplifier for amplifying an output of the DAC and outputting the amplified signal to external; and a digital signal processor for processing an output of the ADC and controlling gain values of the variable-gain input and output amplifiers in correspondence with the determined communication distance.

The digital signal processor stores information that enables the optimal gain value to be selected in accordance with the determined communication distance. The digital signal processor operates to tract the optimal gain value according to the determined communication distance at the beginning of operation in the communication system.

The digital signal processor of the present invention selects a gain value of the variable gain controller from an intermediate value of gain values in the available gain control range (or a cognizable range) when the first or second transceiver is moving. The available gain control range is the extension that can be traced for migration of a target in accordance with the optimal gain value. On the other hand, the digital signal processor selects a gain value of the variable gain controller from the maximum value of gain values in the available gain control range when the first or second transceiver is moving. The maximum cognition distance corresponds to the maximum communication distance detectable by the first and second transceivers. The available gain control range is the extension that can be traced for migration of a target in accordance with the optimal gain value.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

### INDUSTRIAL APPLICABILITY

The present invention is applicable to automatic gain control for communication systems.

1. An automatic gain-control method for a communication system, comprising:
determining a communication distance between the first and second transceivers; and
controlling gain values of transception stages of the first and second transceivers in correspondence with the communication distance.

2. The method as set forth in claim 1, wherein determining the communication distance comprises:
generating an distance determining signal from the first transceiver;
transmitting an distance determining signal from the generated second transceiver;
transmitting an distance determining signal from the transmitted first transceiver; and
calculating the communication distance by means of a time from the generation of the distance determining signal until the transmission of the distance determining signal.

3. The method as set forth in claim 2, wherein the distance determining signal is generated periodically.

4. The method as set forth in claim 1, wherein the gain values of the transception stages increases as long as the determined communication distance, while decreases as short as the determined communication distance.

5. The method as set forth in claim 1, wherein the first and second transceivers track optimal gain values in accordance with the determined communication distance at the beginning of operation in the communication system.

6. The method as set forth in claim 5, wherein an intermediate value among gain values in an available gain control range is selected as the gain value of the transception stage when the first or second transceiver is moving,
wherein the available gain control range is the extension traceable for migration of a target in accordance with the optimal gain value.

7. The method as set forth in claim 5, wherein the maximum value among gain values in an available gain control range is selected as the gain value of the transception stage when the first or second transceiver is positioned at the maximum cognition distance during migration,
wherein the maximum cognition distance corresponds to the maximum communication distance cognizable by the first and second transceivers,
wherein the available gain control range is the extension traceable for migration of a target in accordance with the optimal gain value.

8. An automatic gain controller comprising:
a variable-gain input amplifier amplifying a signal input from external;
an analog-digital converter converting an output signal of the variable-gain input amplifier into a digital signal;
a digital-analog converter converting an internal digital signal into an analog signal;
a variable-gain output amplifier amplifying an output of the digital-analog converter and outputting the amplified signal to the external; and
a digital signal processor processing an output of the analog-digital converter and controlling gain values of the variable-gain input and output amplifiers in correspondence with a communication distance.

9. The automatic gain controller as set forth in claim 8, wherein the digital signal processor comprises:
an distance determiner calibrating the communication distance; and
a gain controller adjusting the gain values of the variable-gain input and output amplifiers in correspondence with the communication distance.

10. A transceiver comprising:
an distance determiner calibrating a communication distance; and
an automatic gain controller maintaining an output of an amplifier in accordance with the communication distance.

11. The transceiver as set forth in claim 10, wherein the automatic gain controller comprises:
a variable-gain input amplifier amplifying a signal input from external;
an analog-digital converter converting an output signal of the variable-gain input amplifier into a digital signal;
a digital-analog converter converting an internal digital signal into an analog signal;
a variable-gain output amplifier amplifying an output of the digital-analog converter and outputting the amplified signal to the external; and
a digital signal processor processing an output of the analog-digital converter and controlling gain values of the variable-gain input and output amplifiers in correspondence with the communication distance taken by the distance determiner.
